(19) United States
(12) Patent Application Publication
(10) Pub. No.: US 2026/0169528 A1
(43) Pub. Date: Jun. 18, 2026

(54) DISPLAY DEVICE

(71) Applicant: LG ELECTRONICS INC., Seoul (KR)

(72) Inventors: Byungkil LIM, Seoul (KR); Seokjung KANG, Seoul (KR); Youngkeun CHOI, Seoul (KR)

(73) Assignee: LG ELECTRONICS INC., Seoul (KR)

(21) Appl. No.: 19/129,281

(22) PCT Filed: Nov. 11, 2022
(86) PCT No.: PCT/KR2022/017686

§ 371 Date: May 12, 2025

(51) Int. Cl. G06F 1/16; G02F 1/1333; G09F 9/30; H10K 59/131

(52) U.S. Cl. CPC G06F 1/1652; G02F 1/133305; G02F 1/133317; G06F 1/1601; G06F 1/1637; G09F 9/301; H10K 59/131

(57) ABSTRACT

A display device is provided. The display device includes: a display panel including at least one corner; a side frame including a horizontal portion extending along one side of the display panel from the at least one corner and facing a rear surface of the display panel, and a vertical portion extending in a direction intersecting the horizontal portion and covering the one side of the display panel; and a support member fixed to the horizontal portion at a position between the rear surface of the display panel, which is adjacent to the at least one corner, and the horizontal portion of the side frame, the support member supporting a rear surface of the corner of the display panel.

### TECHNICAL FIELD

This disclosure relates to a display device.

### BACKGROUND ART

With the development of the information society, there has been a growing demand for various types of display devices, and in order to meet such demand, various display devices, such as a liquid crystal display (LCD), a plasma display panel (PDP), an electroluminescent display (ELD), a vacuum fluorescent display (VFD), an organic light emitting diode (OLED), etc., have been studied and used recently.

Among them, the LCD panel includes a TFT substrate and a color substrate which are positioned opposite each other with a liquid crystal layer interposed therebetween, and displays an image by using light provided by a backlight unit. Further, the OLED panel may display an image by using a self-emitting organic layer deposited on a substrate on which transparent electrodes are formed.

Particularly, a display device using the OLED panel has excellent luminance and viewing angle characteristics compared to a liquid crystal display device and requires no backlight unit, such that the OLED display device can be implemented as an ultra-thin display device.

Recently, many studies have been conducted on an ultra-thin large screen display device.

### DISCLOSURE OF INVENTION

### Technical Problem

It is an objective of the present disclosure to solve the above and other problems.

It is another objective of the present disclosure to ensure structural rigidity of an ultra-thin large screen display device.

It is yet another objective of the present disclosure to provide a display device capable of preventing damage to a display panel.

### Solution to Problem

In accordance with an aspect of the present disclosure, the above and other objectives can be accomplished by providing a display device including: a display panel including at least one corner; a side frame including a horizontal portion extending along one side of the display panel from the at least one corner and facing a rear surface of the display panel, and a vertical portion extending in a direction intersecting the horizontal portion and covering the one side of the display panel; and a support member fixed to the horizontal portion at a position between the rear surface of the display panel, which is adjacent to the at least one corner, and the horizontal portion of the side frame, the support member supporting a rear surface of the corner of the display panel.

### Advantageous Effects of Disclosure

The display device according to the present disclosure has the following effects.

According to at least one of the embodiments of the present disclosure, structural rigidity of an ultra-thin large screen display device may be ensured.

According to at least one of the embodiments of the present disclosure, a display device capable of preventing damage to a display panel may be provided.

Further scope of applicability of the present disclosure will become apparent from the detailed description given hereinafter. However, it should be understood that the detailed description and specific examples, while indicating preferred embodiments of the present disclosure, are given by illustration only, since various changes and modifications within the spirit and scope of the present disclosure will become apparent to those skilled in the art from this detailed description.

### BRIEF DESCRIPTION OF DRAWINGS

FIGS. 1 to 24 are diagrams illustrating examples of a display device according to embodiments of the present disclosure.

### MODE OF DISCLOSURE

Hereinafter, the present disclosure will be described in detail with reference to the accompanying drawings, in which the same reference numerals are used throughout the drawings to designate the same or similar components, and a redundant description thereof will be omitted.

The suffixes, such as “module” and “unit,” for elements used in the following description are given simply in view of the ease of the description, and do not have a distinguishing meaning or role.

In addition, it will be noted that a detailed description of known arts will be omitted if it is determined that the detailed description of the known arts can obscure the embodiments of the present disclosure. Further, the accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms, “first,” “second,” etc., may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A singular representation may include a plural representation unless context clearly indicates otherwise.

It should be understood that the terms, “comprise,” “include,” “have,” etc. when used in this specification, specify the presence of stated features, integers, steps, operations, elements, components, or combinations thereof but do not preclude the presence or addition of one or more other features, integers, steps, operations, elements, components, or combinations thereof.

References to directions, such as up (U), down (D), left (Le), right (Ri), front (F), and rear (R), shown in the drawings are provided merely for convenience of explanation and are not intended for limiting the scope of the present disclosure.

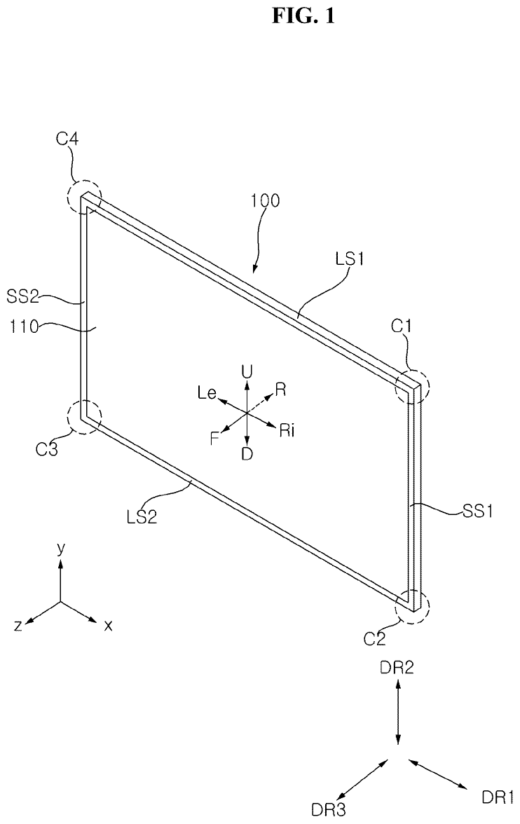

Referring to FIG. 1, a display device 100 may include a display panel 110. The display panel 110 may display an image.

The display device 100 may include a first long side LS1, a second long side LS2 opposite to the first long side LS1, a first short side SS1 adjacent to the first long side LS1 and the second long side LS2, and a second short side SS2 opposite to the first short side SS1. For convenience of explanation, it is illustrated and described that the first and second long sides LS1 and LS2 are longer than the first and second short sides SS1 and SS2, but it is also possible that lengths of the first and second long sides LS1 and LS2 may be approximately equal to lengths of the first and second short sides SS1 and SS2.

A direction parallel to the long sides LS1 and LS2 of the display device 100 may be referred to as a first direction DR1 or a left-right direction. A direction parallel to the short sides SS1 and SS2 of the display device 100 may be referred to as a second direction DR2 or an up-down direction. A direction perpendicular to the long sides LS1 and LS2 and the short sides SS1 and SS2 of the display device 100 may be referred to as a third direction DR3 or a front-rear direction.

A side on which the display device 100 displays an image may be referred to as a front side F, +z, and a side opposite thereto may be referred to as a rear side R, −z. The second short side SS2 may be referred to as a left side Le, −x, and the first short side SS1 may be referred to as a right side Ri, +x. The first long side LS1 may be referred to as an upper side U, +y, and the second long side LS2 may be referred to as a lower side D, −y.

The first long side LS1, the second long side LS2, the first short side SS1, and the second short side SS2 may be referred to as edges of the display device 100. Further, positions where the first long side LS1, the second long side LS2, the first short side SS1, and the second short side SS2 meet each other may be referred to as corners.

A position where the first short side SS1 and the first long side LS1 meet may be referred to as a first corner C1. A position where the first short side SS1 and the second long side LS2 meet may be referred to as a second corner C2. A position where the second short side SS2 and the second long side LS2 meet may be referred to as a third corner C3. A position where the second short side SS2 and the first long side LS1 meet may be referred to as a fourth corner C4.

Hereinafter, a display panel using an organic light emitting diode (OLED) will be described as an example of the display panel 110, but the display panel 110 applicable to the present disclosure is not limited thereto.

The display panel 110 may define a front surface of the display device 100 and may display an image forward. The display panel 110 may divide an image into a plurality of pixels and may output the image while controlling color, brightness, and chroma of the respective pixels. The display panel 110 may be divided into an active area, in which images are displayed, and a de-active area in which images are not displayed. The display panel 110 may generate light corresponding to red, green, or blue color in response to a control signal.

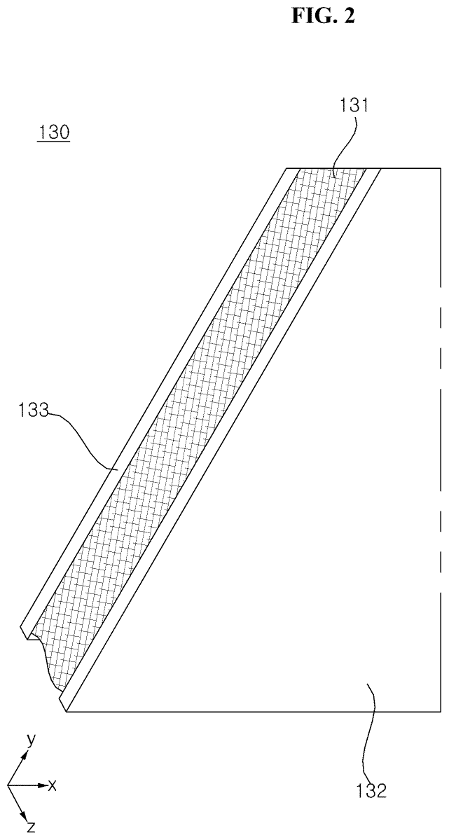

Referring to FIG. 2, a material complexed panel 130 may include a core 131, a front skin 132, and a rear skin 133. The core 131, the front skin 132, and the rear skin 133 may be coupled or bonded to each other. The material complexed panel 130 may be referred to as a fiber complexed panel 130, a fiber complexed plate 130, a material complexed plate 130, or a frame 130.

The front skin 132 may define a front surface of the material complexed panel 130. The rear skin 133 may define a rear surface of the material complexed panel 130. The front skin 132 and the rear skin 133 may include a metal material. For example, the front skin 132 and the rear skin 133 may include an aluminum (Al) material. In another example, the front skin 132 and the rear skin 133 may be galvanized iron (Galvanized Steel Sheet). For example, the front skin 132 and the rear skin 133 may have a thickness of about 0.5 mm. The front skin 132 and the rear skin 133 may be disposed opposite each other with respect to the core 131.

The core 131 may be positioned between the front skin 132 and the rear skin 133. The core 131 may include fibers. The core 131 may be made of a composite material. The core 131 may include a main fiber and a binder fiber. The binder fiber may be mixed with the main fiber.

A hot-melt sheet may be disposed between the front skin 132 and the core 131. In addition, the hot-melt sheet may be disposed between the rear skin 133 and the core 131. The hot-melt sheet may be a film. For example, the hot-melt sheet may be a film, such as EVA, acryl, polyurethane, etc., which has a thickness of 50 micrometers or more. Lamination of the core 131 and the hot-melt sheet onto the front skin 132 and the rear skin 133 may be performed at a high temperature (e.g., about 190° C. to 200 ° C.) for 1 minute or more.

Accordingly, the material complexed panel 130 may improve bending rigidity and/or torsional rigidity of the display device.

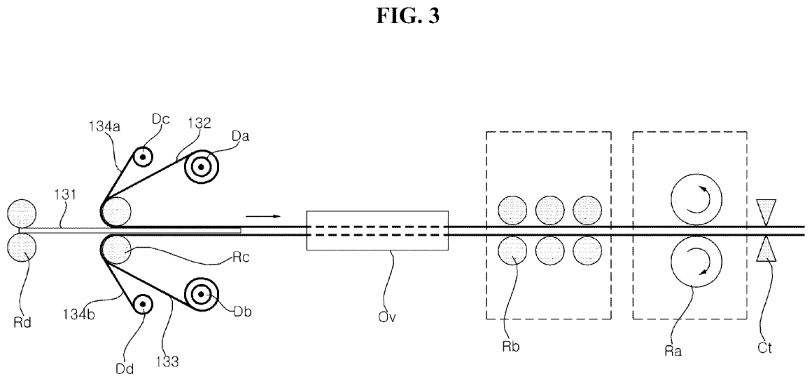

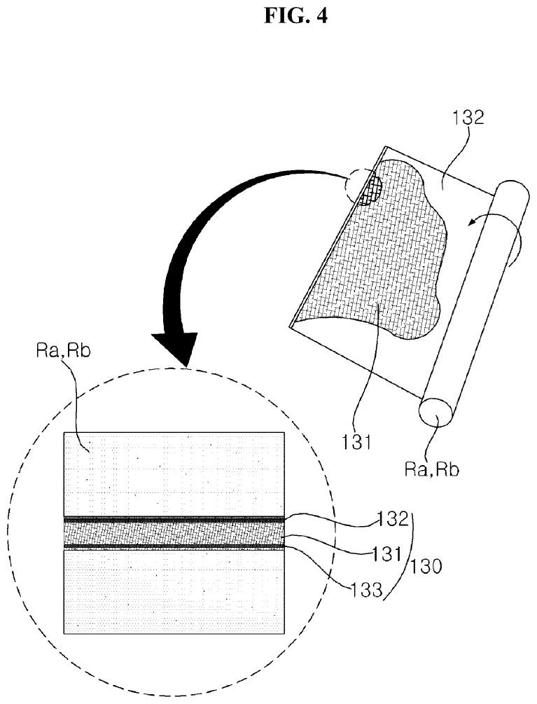

Referring to FIGS. 3 and 4, the material complexed panel 130 may be manufactured through a process of pressing the front skin 132 and the rear skin 133 to the core 131 using a plurality of rollers, and this process may be referred to as a roll-to-roll (R2R) process.

Referring to FIG. 3, according to the rotation of a pinch roller Ra performing the function of a drive motor, the front skin 132 may be unwound from a front drum Da, the rear skin 133 may be unwound from a rear drum Db, and the core 131 may be moved through a feeding roller Rd. In addition, a first adhesive 134a for coupling the front skin 132 to the core 131 may be unwound from a first drum Dc. Also, a second adhesive 134b for coupling the rear skin 133 to the core 131 may be unwound from a second drum Db. In this case, the front skin 132, the first adhesive 134a, the core 131, the second adhesive 134 b, and the rear skin 133 are stacked in this order, and may be guided toward an oven Ov by a guide roller Rc. The adhesive 134a and 134b may be the hot-melt sheet 134a and 134b.

The first and second adhesives 134a and 134b are melted in the oven Ov, and each of the front skin 132 and the rear skin 133 may be coupled to the core 131. For example, the melting point of the first and second adhesives 134a and 134b may be about 150° C., and the atmosphere temperature of the oven Ov may be about 200° C. For example, the peel-off force of the first and second adhesives 134a and 134b may be about 10 kgf or more.

The front skin 132, the core 131, and the rear skin 133 that have passed through the oven Ov may be guided to a pressing roller Rb and compressed by the pressing roller Rb, according to the rotation of the pinch roller Ra. Accordingly, the mutual coupling force among the front skin 132, the core 131, and the rear skin 133 may be further increased. The front skin 132, the core 131, and the rear skin 133 that are coupled to each other may pass through the pinch roller Ra, and then may be cut by a cutter Ct to be produced as a material complexed panel 130 of a predetermined size.

Referring to FIG. 4, the pressing roller Rb or the pinch roller Ra may contact an outer surface of each of the front skin 132 and the rear skin 133. When the pressing roller Rb or the pinch roller Ra rotates, the material complexed panel 130 may be moved in a longitudinal direction of the core 131. In this case, the front skin 132 and the rear skin 133 may be may be coupled to the core 131 sequentially from one end to the other end in the longitudinal direction of the core 131.

In addition, the front skin 132 and the rear skin 133 of the material complexed panel 130 may be formed to be flat. That is, as the rear surface of the rear skin 133 that defines the rear surface of the display device 100 is formed to be flat, an additional process, such as painting the rear surface of the rear skin 133, attaching a sheet thereto, or the like, for an aesthetically pleasing appearance may be easily performed. Alternatively, the flat rear skin 133 itself may define the rear surface of the display device 100.

Meanwhile, in addition to the R2R process described above with reference to FIGS. 3 and 4, a process of sequentially stacking the front skin 132, the core 131, and the rear skin 133 followed by coupling the same may be used to manufacture the material complexed panel 130.

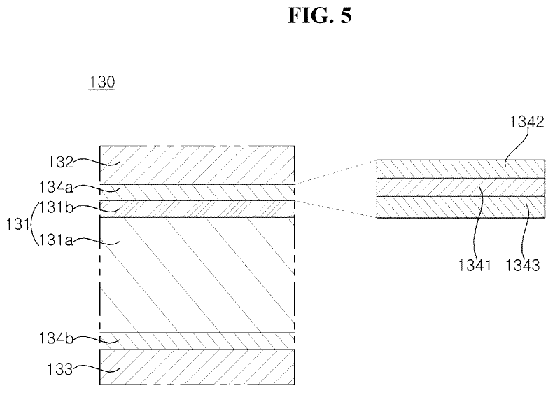

Referring to FIG. 5, the core 131 may include a main core 131a and a binder core 131b. The main core 131a may include a first fiber made of polyethylene terephthalate (PET) and a second fiber made of long material (LM). For example, the main core 131a may contain 50% of the first fiber and 50% of the second fiber. The binder core 131b may include an acrylic fiber.

The front skin 132 may include an aluminum (Al) material or Galvanized Iron and may be coupled to the binder core 131b by the first hot-melt adhesive 134a.

The rear skin 133 may include an aluminum (Al) material or Galvanized Iron and may be coupled to the main core 131a by the second hot-melt adhesive 134b.

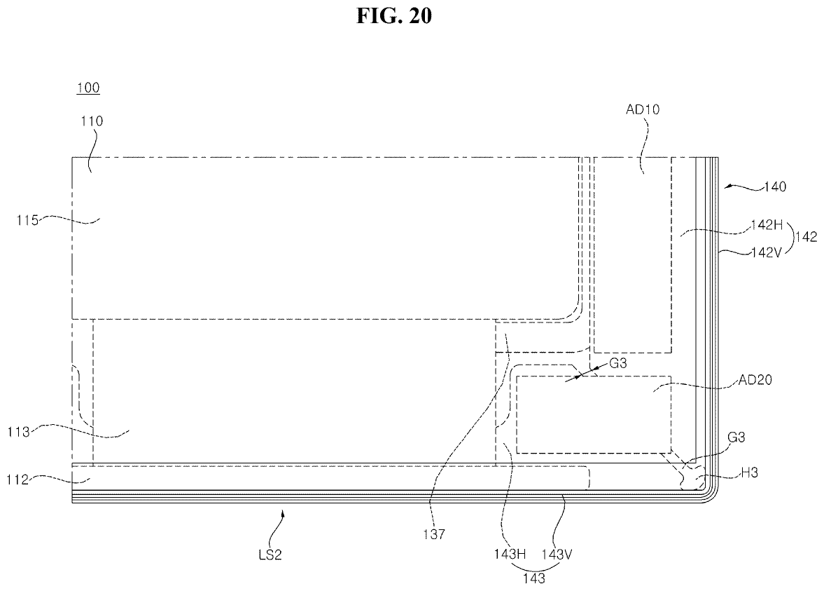

The front skin 132 may be located closer to the display panel 110 (see FIG. 20) than the rear skin 133 and may be exposed to a relatively high temperature compared to the rear skin 133. That is, there may be a temperature difference between the front skin 132 and the rear skin 133. For example, the temperature difference between the front skin 132 and the rea skin 133 may be about 4° C.

In this case, the hot-melt adhesives 134a and 134b may have a multi-layered structure including multiple layers of fabric material. The hot-melt adhesives 134a and 134b may include a first layer 1341, a second layer 1342, and a third layer 1343. For example, the first layer 1341, the second layer 1342, and the third layer 1343 may include a synthetic fiber material. For example, the first layer 1341 may include a nylon material and may be disposed between the second layer 1342 and the third layer 1343. For example, the second layer 1342 and the third layer 1343 may include a polyurethane (PU) material.

Accordingly, elongation properties of the respective layers of the material complexed panel 130 may minimize warping caused by thermal deformation of the material complexed panel 130, which is due to a temperature difference between the front skin 132 and the rear skin 133.

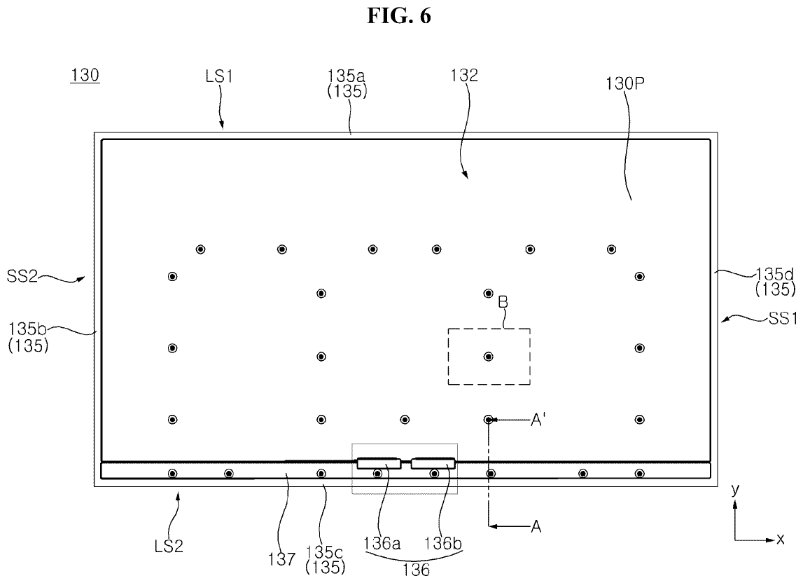

Referring to FIG. 6, the material complexed panel 130 may include a flat part 130P, an outer part 135, and a receiving part 137. The front skin 132 of the material complexed panel 130 may define a front surface of each of the flat part 130P, the outer part 135, and the receiving part 137.

The outer part 135 may be formed around the flat part 130P. The outer part 135 may be formed by being pressed rearward from the flat part 130P. A first outer part 135a may be formed along an upper side of the flat part 130P. A second outer part 135b may be formed along a right side of the flat part 130P. A third outer part 135c may be formed along a lower side of the flat part 130P. A fourth outer part 135d may be formed along a left side of the flat part 130P.

The receiving part 137 may be defined between the flat part 130P and the third outer part 135c. The receiving part 137 may be formed by being pressed rearward from the flat part 130P and/or the third outer part 135c.

The cable hole 136 may be formed through the receiving part 137 in the front-rear direction. For example, a plurality of cable holes 136a and 136b may be adjacent to each other.

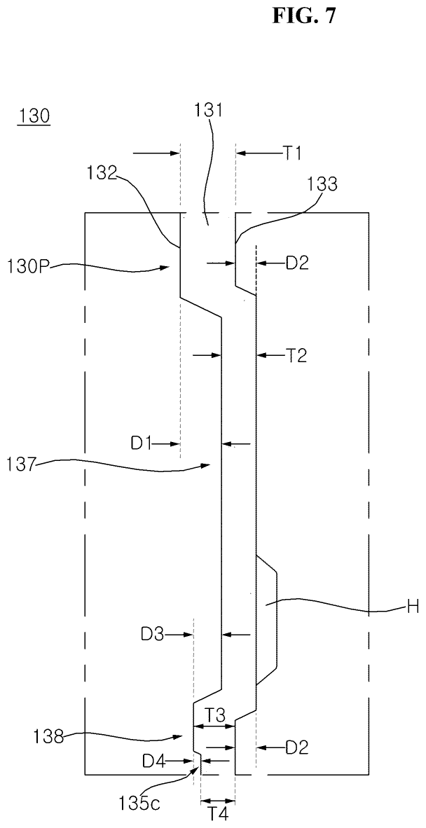

Referring to FIG. 7, a thickness T1 of the flat part 130P may be greater than a thickness T2 of the receiving part 137. A step DI between the front skin 132 of the flat part 130P and the front skin 132 of the receiving part 137 may be greater than a step D2 between the rear skin 133 of the flat part 130P and the rear skin 133 of the receiving part 137.

A thickness T4 of the third outer part 135c may be greater than the thickness T2 of the receiving part 137. A step D2 between the rear skin 133 of the third outer part 135c and the rear skin 133 of the receiving part 137 may be equal to the step D2 between the rear skin 133 of the flat part 130P and the rear skin 133 of the receiving part 137.

A protrusion pad 138 may protrude forward from the front skin 132 of the third outer part 135c. A thickness T3 of the protrusion pad 138 may be greater than the thickness T4 of the third outer part 135c, may be greater than the thickness T2 of the receiving part 137, and may be less than the thickness T1 of the flat part 130P. A step D4 between the front skin 132 of the protrusion pad 138 and the front skin 132 of the third outer part 135c may be less than the steps D1, D2, and D3. The step D3, descending from the front skin 132 of the protrusion pad 138 to the front skin 132 of the receiving part 137, may be smaller than the step D1 and greater than the step D2.

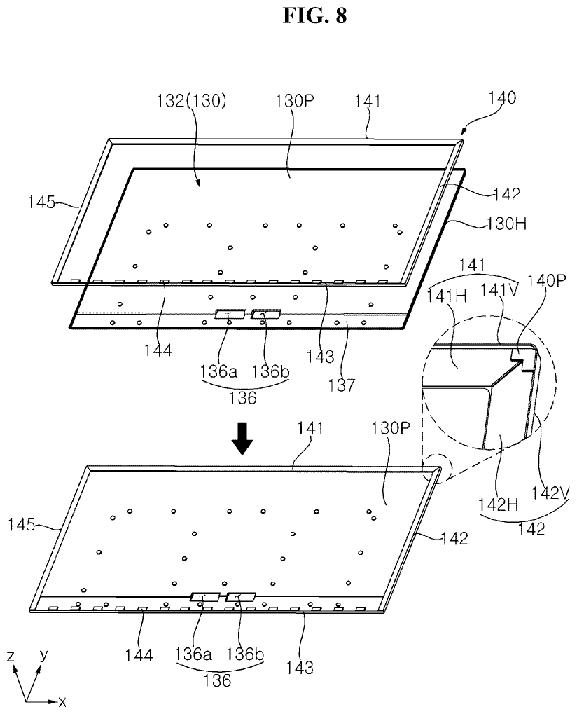

Referring to FIG. 8, a side frame 140 may extend along a periphery of the material complexed panel 130. The side frame 140 may be coupled to the front skin 132 of the outer part 135 (see FIG. 6) of the material complexed panel 130 by a hot-melt adhesive 130H. For example, the side frame 140 may include a metal material such as aluminum (Al). The side frame 140 may be referred to as a guide panel 140 or a middle cabinet 140.

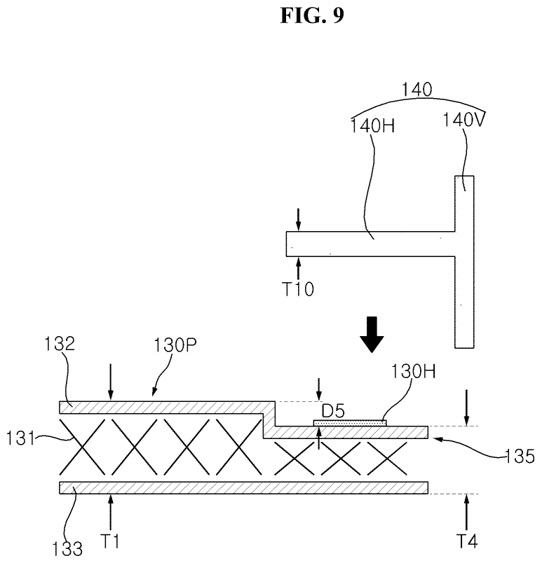

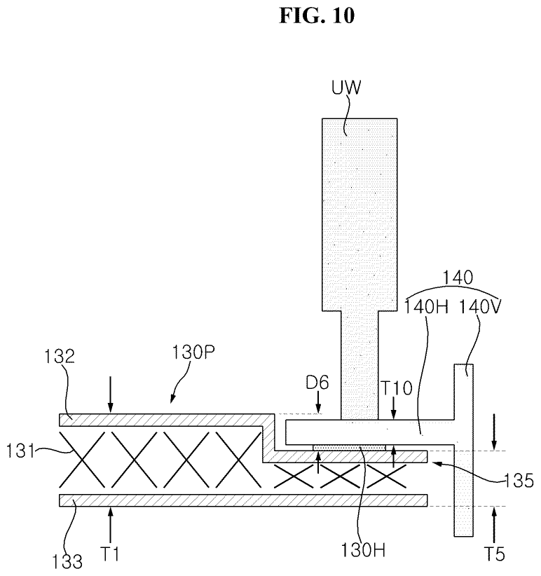

Referring to FIGS. 9 and 10, the side frame 140 may include a vertical portion 140V and a horizontal portion 140H. The vertical portion 140V may extend in a front-rear direction and may cover a side surface of the material complexed panel 130. The horizontal portion 140H may extend in a direction intersecting the vertical portion 140V and may be disposed at the front of the outer part 135.

Referring to FIG. 9, the outer part 135 may be formed by being pressed rearward from the front skin 132 of the flat part 130P. For example, after forging, re-striking may be performed to flatten the outer part 135. For example, the thickness T1 of the flat part 130P may be 4.0 mm, and the thickness T4 of the outer part 135 may be 3.0 mm. The hot-melt adhesive 130H may be applied onto the outer part 135, and may be positioned between the outer part 135 and the horizontal portion 140H.

Referring to FIG. 10, a horn UW of an ultrasonic welder may be placed on a front surface of the horizontal portion 140H and may apply ultrasonic vibration to the horizontal portion 140H and the hot-melt adhesive 130H. Accordingly, the horizontal portion 140H may be ultrasonic welded to the outer part 135 through the hot-melt adhesive 130H. In this case, the front skin 132 of the outer part 135 may be pressed toward the rear skin 133 by the horn UW, and a thickness T5 of the outer part 135 may be reduced. For example, the thickness T5 of the outer part 135 may be 2.4 mm to 2.5 mm. A pressed amount D6-D5 of the outer part 135 pressed by the horn UW may be 0.5 mm to 0.6 mm. As the outer part 135 is pressed during the ultrasonic welding described above, i.e., under high-temperature conditions, the outer part 135 may retain its shape without spring-back.

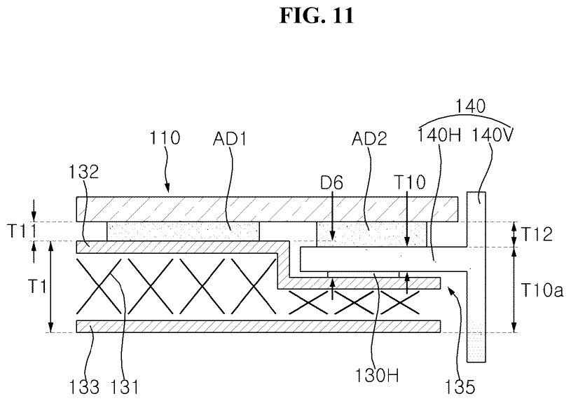

Referring to FIGS. 10 and 11, a sum T10a of the thickness T5 of the outer part 135, the thickness of the hot-melt adhesive 130H, and a thickness T10 of the horizontal portion 140H may be less than the thickness T1 of the flat part 130P. For example, the thickness T1 of the flat part 130P may be 0.4 mm. For example, the thickness T5 of the outer part 135 may be 2.4 mm to 2.5 mm, the thickness of the hot-melt adhesive 130H may be 0.1 mm, the thickness T10 of the horizontal portion 140H may be 1.1 mm, and thus the sum T10a of them may be 3.6 mm to 3.7 mm.

The display panel 110 may be disposed at the front of the horizontal portion 140H. A first adhesive member AD1 may be disposed between the front skin 132 of the flat part 130P and a rear surface of the display panel 110, and may be coupled to the flat part 130P and the display panel 110. For example, a thickness T11 of the first adhesive member AD1 may be 0.5 mm. A second adhesive member AD2 may be disposed between the front surface of the horizontal portion 140H and the rear surface of the display panel 110 and may be coupled to the horizontal portion 140H and the display panel 110. For example, a thickness T12 of the second adhesive member AD2 may be 0.8 mm to 0.9 mm. For example, the adhesive member AD1 and AD2 may be double-sided tape.

Accordingly, the display panel 110 may be coupled to the material complexed panel 130 and the side frame 140, and may be positioned flat with respect to the material complexed panel 130. In addition, the vertical portion 140V may cover a side surface of the display panel 110.

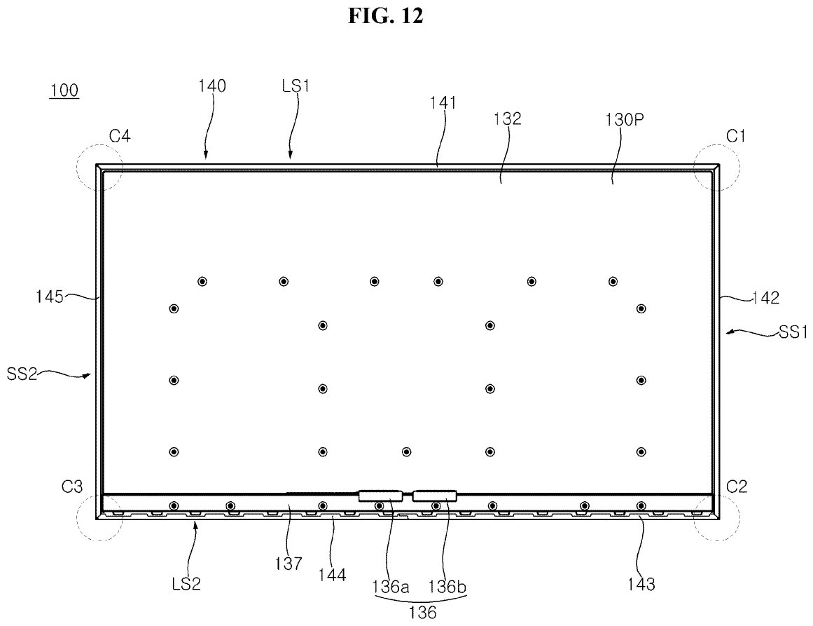

Referring to FIGS. 8 and 12, the side frame 140 may include a first part 141, a second part 142, a third part 143, a fourth part 144, and a fifth part 145.

The first part 141 may extend along the first outer part 135a (see FIG. 6) and may include a first horizontal portion 141H (see FIG. 9) and a first vertical portion 141V. The first horizontal portion 141H may be parallel to the first outer part 135a and may be fixed on the first outer part 135a by the hot-melt adhesive 130H. The first vertical portion 141V may intersect the horizontal portion 141H and may cover the top of the material complexed panel 130.

The second part 142 may be bent downward from a right end of the first part 141 (see the first corner C1) and may include a second horizontal portion 142H and a second vertical portion 142V. The second horizontal portion 142H may be parallel to the second outer part 135b and may be fixed on the second outer part 135b by the hot-melt adhesive 130H. The second vertical portion 142V may intersect the second horizontal portion 142H and may cover the right side of the material complexed panel 130.

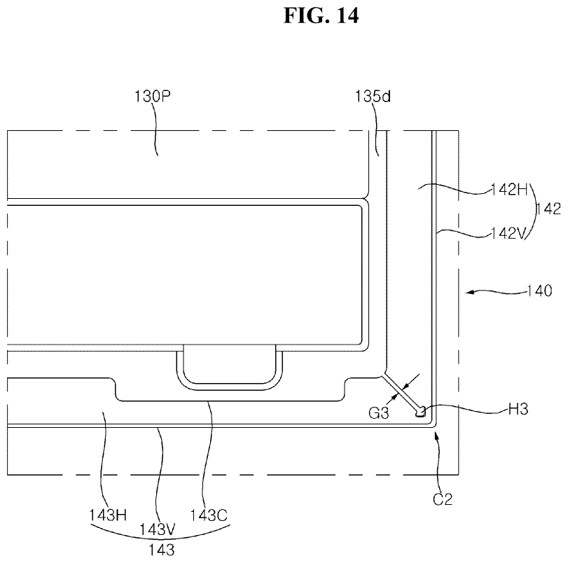

The third part 143 may be bent leftward from a lower end of the second part 142 (see the second corner C2) and may include a third horizontal portion 143H (see FIG. 14) and a third vertical portion 143V. The third horizontal portion 143H may be parallel to the third outer part 135c and may be fixed on the third outer part 135c by the hot-melt adhesive 130H. The third vertical portion 143V may intersect the third horizontal portion 143H and may cover the bottom of the material complexed panel 130.

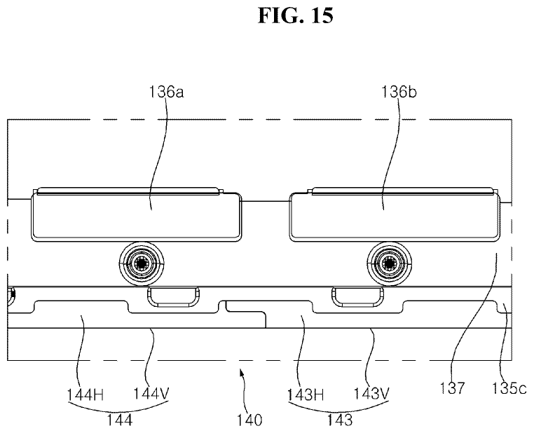

The fourth part 144 may be aligned with the third part 143 along the third outer part 135c, and an end of the fourth part 144 may be connected to an end of the third part 143. The fourth part 144 may include a fourth horizontal portion 144H (see FIG. 15) and a fourth vertical portion 144V (see FIG. 15). The fourth horizontal portion 144H may be parallel to the third outer part 135c and may be fixed on the third outer part 135c by the hot-melt adhesive 130H. The fourth vertical portion 144V may intersect the fourth horizontal portion 144H and may cover the bottom of the material complexed panel 130.

The fifth part 145 may be bent downward from a left end of the first part 141 (see the fourth corner C4), and the fourth part 144 may be bent rightward from a lower end of the fifth part 145 (see the third corner C3). The fifth part 145 may include a fifth horizontal portion (not shown) and a fifth vertical portion (not shown). The fifth horizontal portion (not shown) may be parallel to the fourth outer part 135d and may be fixed on the fourth outer part 135d by the hot-melt adhesive 130H. The fifth vertical portion (not shown) may intersect the fifth horizontal portion (not shown) and may cover the left side of the material complexed panel 130.

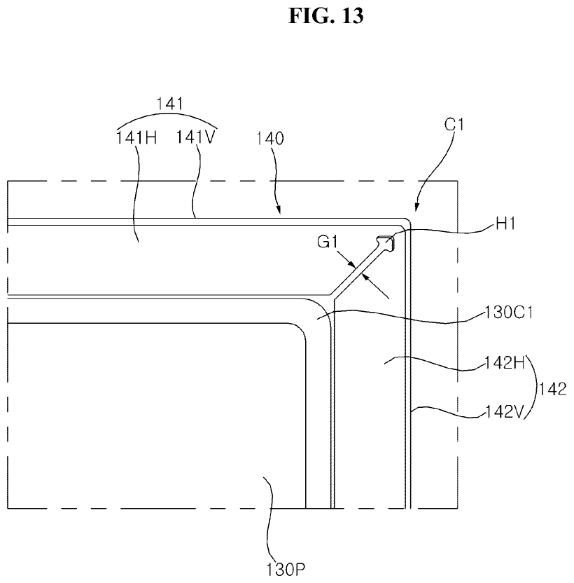

Referring to FIGS. 13 and 14, a gap G1 may be formed between the first horizontal portion 141H of the first part 141 and the second horizontal portion 142H of the second part 142. The first vertical portion 141V of the first part 141 and the second vertical portion 142V of the second part 142 may be connected while being bent. A hole H1 may be adjacent to the vertical portions 141V and 142V, may be connected to the gap G1, and may have a larger diameter than the gap G1.

In addition, a gap, such as the gap G1, may be formed between the first horizontal portion 141H of the first part 141 and the fifth horizontal portion (not shown) of the fifth part 145 (see FIG. 12). The first vertical portion 141V of the first part 141 and the fifth vertical portion (not shown) of the fifth part 142 may be connected while being bent. A hole, such as the hole H1, may be adjacent to the first vertical portion 141V and the fifth vertical portion (not shown).

A gap G3 may be formed between the second horizontal portion 142H of the second part 142 and the third horizontal portion 143H of the third part 143. The second vertical portion 142V of the second part 142 and the third vertical portion 143V of the third part 143 may be connected while being bent. A hole H3 may be adjacent to the vertical portions 142V and 143V, may be connected to the gap G3, and may have a larger diameter than the gap G3.

In addition, a gap, such as the gap G3, may be formed between the fifth horizontal portion (not shown) of the fifth part 145 (see FIG. 12) and the fourth horizontal portion 144H (see FIG. 15) of the fourth part 144 (see FIG. 12). The fifth vertical portion (not shown) of the fifth part 145 and the fourth vertical portion 144V (see FIG. 15) of the fourth part 144 may be connected while being bent. A hole, such as the hole H3, may be adjacent to the fifth vertical portion (not shown) and the fourth vertical portion 144V.

Referring to FIG. 13, a corner 130C1 adjacent to the first corner C1 of the flat part 130P may be rounded. For example, a radius of curvature of the corner 130C1 may be 10 mm. Accordingly, in the aforementioned processes of forging the outer part 135 relative to the flat part 130P and pressing the outer part 135 by using the horn UW (see FIG. 10) of the ultrasonic welder, it may be advantageous to maintain flatness of a portion (see FIG. 6) adjacent to the first corner C1 between the first outer part 135a and the second outer part 135b.

In addition, a corner adjacent to the fourth corner C4 (see FIG. 12) of the flat part 130P may also be rounded like the corner 130C1.

Referring to FIG. 14, a corner 130C2 adjacent to the second corner C2 of the flat part 130P may be rounded. For example, a radius of curvature of the corner 130C2 may be 10 mm. Accordingly, in the aforementioned processes of forging the outer part 135 relative to the flat part 130P and pressing the outer part 135 by using the horn UW (see FIG. 10) of the ultrasonic welder, it may be advantageous to maintain flatness of a portion (see FIG. 6) adjacent to the second corner C2 between the second outer part 135b and the third outer part 135c.

In addition, a corner adjacent to the third corner C3 (see FIG. 12) of the flat part 130P may also be rounded like the corner 130C2.

Referring to FIG. 15, the third horizontal portion 143H of the third part 143 may contact the fourth horizontal portion 144H of the fourth part 144. The third vertical portion 143V of the third part 143 may contact the fourth vertical portion 144V of the fourth part 144. An end of the third part 143 may be coupled to an end of the fourth part 144. For example, the end of the third part 143 may be welded to the end of the fourth part 144.

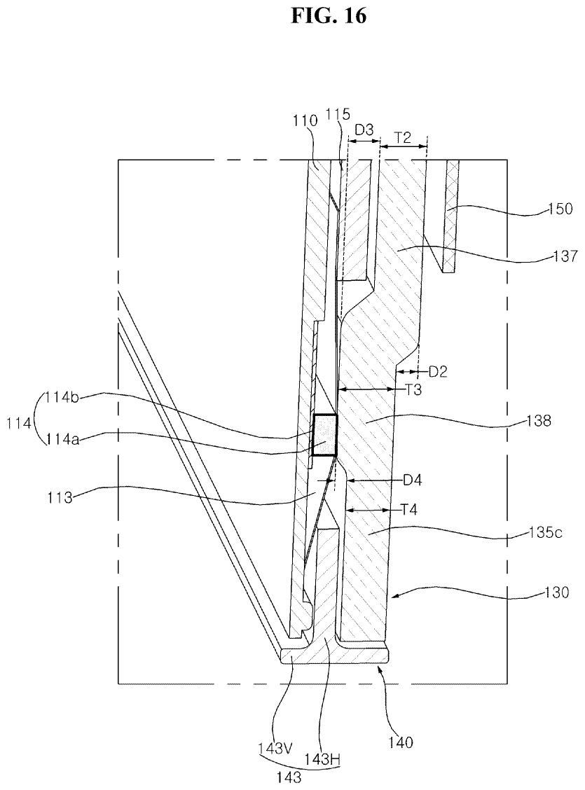

Referring to FIG. 16 along with FIG. 15, the display panel 110 may be coupled or fixed on the side frame 140. The horizontal portion 143H of the side frame 140 may support the rear surface of the display panel 110, and the vertical portion 143V thereof may cover the side surface of the display panel 110. For example, the vertical portion 143V of the third part 143 of the side frame 140 may cover the side surface of the lower side of the display panel 110.

The vertical portion 143V may cover the side surface of the material complexed panel 130. For example, the vertical portion 143V of the third part 143 of the side frame 140 may cover the side surface of the third outer part 135c of the material complexed panel 130.

A flexible cable 113 may extend from the lower side of the display panel 110 and between the display panel 110 and the horizontal portion 143H of the side frame 140. The flexible cable 113 may extend between the rear surface of the display panel 110 and the material complexed panel 130. For example, the flexible cable 113 may be a COF 113.

A source signal board 115 may be electrically connected to the flexible cable 113. The source signal board 115 may be fixed to one surface of the flexible cable 113. For example, the source signal board 115 may be an S-PCB 115. The source signal board 115 may be disposed in the receiving part 137 of the material complexed panel 130.

The flexible cable 113 may be disposed between the protrusion pad 138 of the material complexed panel 130 and the display panel 110. The flexible cable 113 may contact the protrusion pad 138. Heat generated by the source signal board 115 and/or the flexible cable 113 may be dissipated through the protrusion pad 138.

A heat sink pad 114 may be located between the flexible cable 113 in contact with the protrusion pad 138 and the rear surface of the display panel 110. The heat sink pad 114 may include an elastic material 114a and a conductive film 114b. The core 114a of the heat sink pad 114 may be formed of an elastic material, and the conductive film 114b may cover the core 114a of the heat sink pad 114. Accordingly, the flexible cable 113 may remain in contact with the protrusion pad 138.

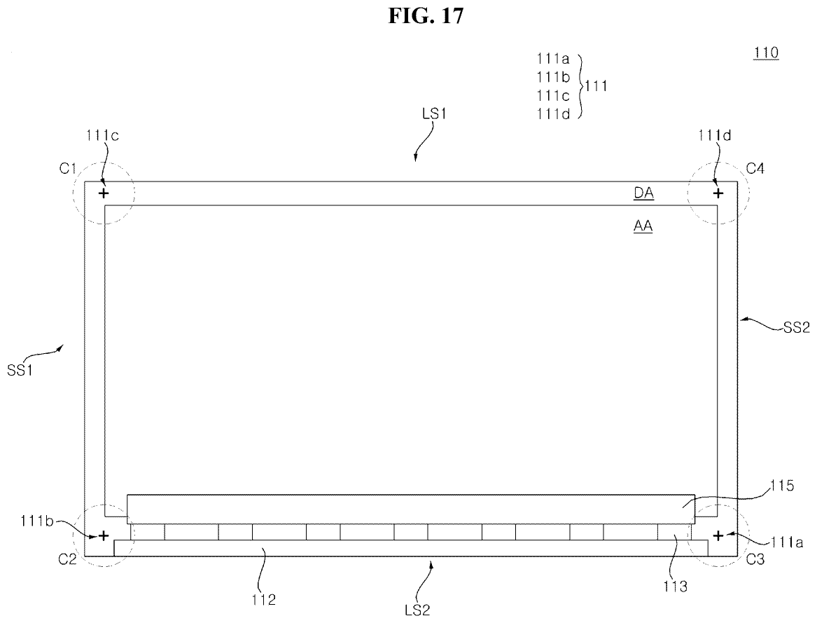

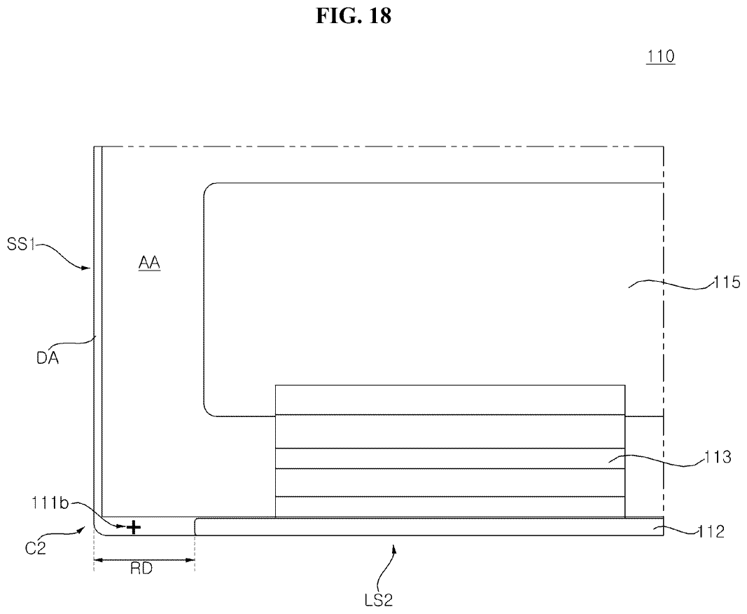

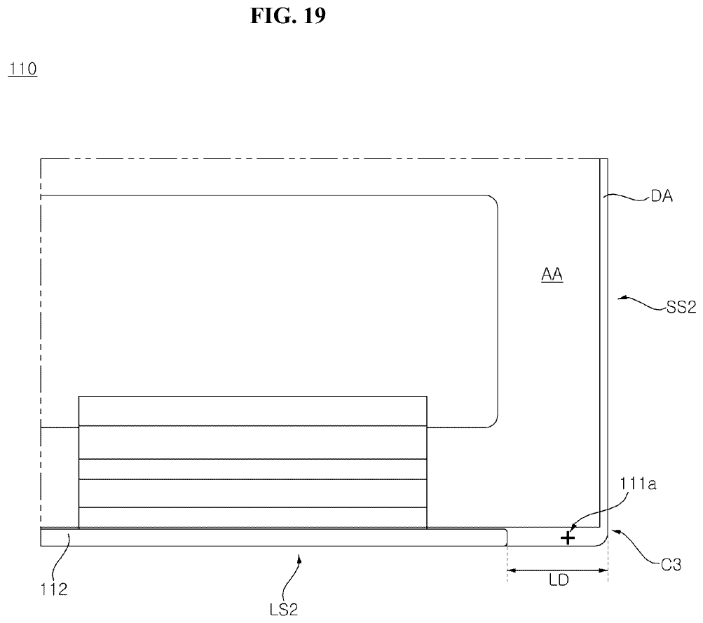

Referring to FIGS. 17 to 19, the display panel 110 may include an active area AA and a de-active area DA. The de-active area DA may be located at the edge of the active area AA. The active area AA may display images. The de-active area DA may be referred to as a bezel DA of the display panel 110.

The flexible cable 113 may be connected to the lower side LS2 of the display panel 110. The source signal board 115 may be connected to the flexible cable 113. The source signal board 115 may provide an image signal to the display panel 110 through the flexible cable 113.

A sealing member 112 may be located in the de-active area DA of the display panel 110 along the lower side LS2 of the display panel 110. For example, the sealing member 112 may be formed by dispensing an insulating material into the bezel DA of the lower side LS2 of the display panel 110 and curing the insulating material. A length of the sealing member 112 may be shorter than a length of the lower side LS2 of the display panel 110. For example, a first distance RD may be formed between a right end of the sealing member 112 and the first short side SS1 of the display panel 110. In another example, a second distance LD may be formed between a left end of the sealing member 112 and the second short side SS2 of the display panel 110. The first distance RD may be substantially equal to the second distance LD.

A processing key 111 may be formed on a rear surface of the bezel DA at the respective corners C1, C2, C3, and C4 of the display panel 110. The processing key 111 may be a mark for mass production of the display panel 110. A production process of the display panel 110 may be performed by identifying the processing key 111. Due to the processing key 111, the first distance RD and the second distance LD may be formed at the lower side LS2 of the bezel DA on the rear surface of the display panel 110.

Referring to FIG. 20, the display panel 110 may be disposed at the front of the material complexed panel 130 (see FIG. 16). The side frames 140, 142, and 143 may include the horizontal portions 142H and 143H and the vertical portions 142V and 143V. The horizontal portions 142H and 143H of the side frames 140, 142, and 143 may be disposed between the display panel 110 and the material complexed panel 130. For example, the horizontal portion 142H of the second part 142 of the side frame 140 may be fixed on the second outer part 135b (see FIG. 6) of the material complexed panel 130. The horizontal portion 143H of the third part 143 of the side frame 140 may be fixed on the third outer part 135c (see FIG. 6) of the material complexed panel 130. The vertical portion 143V of the third part 143 of the side frame 140 may be bent and extend from the vertical portion 142V of the second part 142.

The vertical portions 142V and 143V of the side frames 140, 142, and 143 may intersect the horizontal portions 142H and 143H thereof. The vertical portions 142V and 143V may cover the side surface of the display panel 110 and/or the side surface of the material complexed panel 130.

An adhesive member AD10 may be fixed on the horizontal portion 142H of the second part 142 of the side frame 140. The adhesive member AD10 may be elongated in a longitudinal direction of the second part 142 of the side frame 140. An adhesive member AD20 may be fixed on the horizontal portion 143H of the third part 143 and the horizontal portion 142H of the second part 142. The adhesive member AD20 may cover a gap G3 formed between the horizontal portion 142H of the second part 142 and the horizontal portion 143H of the third part 143.

The sealing member 112 may be elongated along the lower side LS2 of the display panel 110 and may be fixed to the rear surface of the display panel 110 in the de-active area DA (see FIG. 17) of the display panel 110. For example, the sealing member 112 may face the horizontal portion 143H of the third part 143 of the side frame 140 or may contact the horizontal portion 143H, and may be parallel to the vertical portion 143V. In another example, the sealing member 112 may face the vertical portion 143V of the third part 143 of the side frame 140 or may contact the vertical portion 143V, and may be parallel to the horizontal portion 143H.

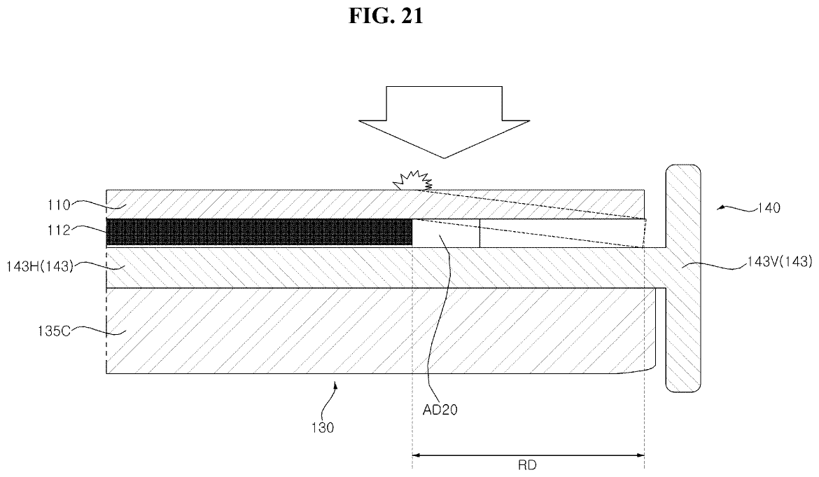

Referring to FIG. 21 along with FIG. 20, the sealing member 112 of the display panel 110 may be attached to the rear surface of the display panel 110 at a position between the display panel 110 and the horizontal portion 143H of the third part 143 of the side frame 140. When an external force is applied over a first distance RD of the display panel 110, the display panel 110 may be bent, particularly from the front to the rear of the display panel 110. For example, when a pressing force that presses the display panel 110 is applied to the front surface of the display panel 110, the display panel 110 may be moved closer to the horizontal portion 143H of the side frame 140. In this case, the sealing member 112 may be supported by the horizontal portion 143H of the side fame 140. The external force applied to the display panel 110 causes the stress of the display panel 110 to concentrate at an end of the sealing member 112, such that the display panel 110 may be damaged.

Referring to FIGS. 10 and 11 along with FIG. 21, as a gap T1 between the display panel 110 (see FIG. 21) and the front skin 132 of the flat part 130P of the material complexed panel 130 decreases, heat generated by the display panel 110 may be easily transferred to the material complexed panel 130, thereby improving the effect of dissipating the heat of the display panel 130. As the gap T1 between the display panel 110 and the front skin 132 of the flat part 130P decreases, a gap between the horizontal portion 143H of the side frame 140 and the display panel 110 (see FIG. 21) also decreases.

Referring to FIG. 21, as the gap between the display panel 110 and the horizontal portion 143H of the side frame 130 decreases, a gap between the sealing member 112 and the horizontal portion 143H also decreases, and a range of deformation of the display panel 110 and/or the sealing member 112 due to the external force applied to the display panel 110 may also be limited. As the gap between the sealing member 112 and the horizontal portion 143H increases, the display panel 110 and the sealing member 112 may be elastically bent even when the external force is applied to the display panel 110. In this case, when the display panel 110 and the sealing member 112 are bent, the display panel 110 is not damaged, and the display panel 110 may be elastically restored from bending when the external force is removed.

By contrast, when the gap between the sealing member 112 and the horizontal portion 143H decreases, the sealing member 112 is supported by the horizontal portion 143H such that the sealing member 112 is not deformed, and the display panel 110 may be deformed at a portion adjacent to the end of the sealing member 112. In this case, the sealing member 112 acts as a lever with respect to the rear surface of the display panel 110, such that the display panel 110 may be damaged at the end of the sealing member 112.

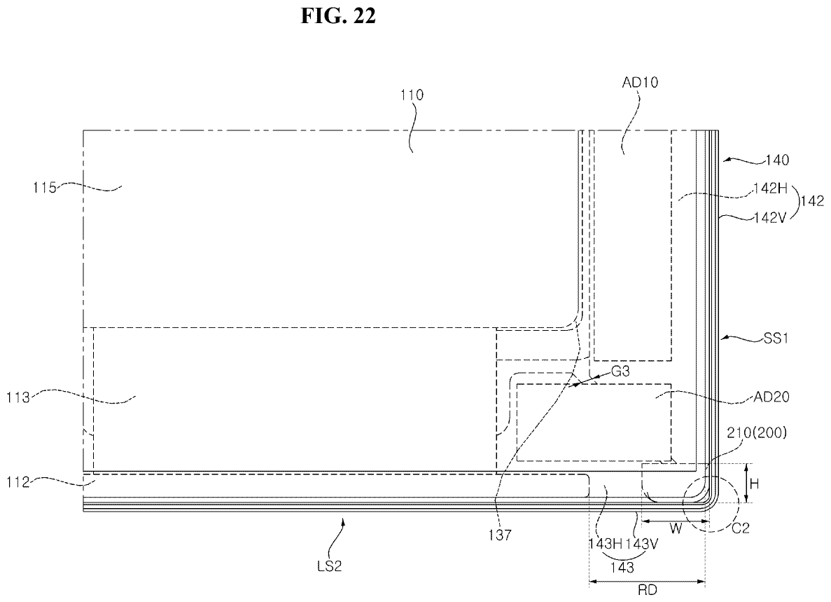

Referring to FIG. 22, the horizontal portion 142H of the second part 142 of the side frame 140 may be fixed on the second outer part 135b (see FIG. 6) of the material complexed panel 130. The horizontal portion 143H of the third part 143 of the side frame 140 may be fixed on the third outer part 135c (see FIG. 6) of the material complexed panel 130. The vertical portion 143V of the third part 143 of the side frame 140 may be bent and extend from the vertical portion 142V of the second part 142.

The adhesive member AD10 may be fixed on the horizontal portion 142H of the second part 142 of the side frame 140. The adhesive member AD10 may be elongated in a longitudinal direction of the second part 142 of the side frame 140. The adhesive member AD20 may be fixed on the horizontal portion 143H of the third part 143 and the horizontal portion 142H of the second part 142. The adhesive member AD20 may cover a gap G3 formed between the horizontal portion 142H of the second part 142 and the horizontal portion 143H of the third part 143.

The display panel 110 may be fixed to the side frame 140 by the adhesive members AD10 and AD20. The source signal board 115 may be received in the receiving part 137 and may be disposed between the material complexed panel 130 and the display panel 110. The sealing member 112 of the display panel 110 may face the horizontal portion 143H of the third part 143 and may be parallel to the vertical portion 143V of the third part 143. The sealing member 112 of the display panel 110 may be disposed between the adhesive member AD20, fixed to the horizontal portion 142H of the second part 142 and the horizontal portion 143H of the third part 143, and the vertical portion 143V of the third part 143. The first distance RD of the display panel 110 may be located at the second corner C2 where the first short side SS1 and the second long side LS2 of the display panel 110 meet.

A support member 210 may be disposed adjacent to the second corner C2. The support member 210 may have a height side H and a width side W. The support member 210 may be fixed to the horizontal portions 142H and 143H while covering the horizontal portion 142H of the second part 142 and the horizontal portion 143H of the third part 143. For example, a size of the width side W may be greater than a size of the height side H. The support members 200, 210, and 220 may be referred to as support members 200, 210, and 220.

The height side H of the support member 210 may contact the vertical portion 142V of the second part 142, and the width side W of the support member 210 may contact the vertical portion 143V of the third part 143. For example, a length of the width side W of the support member 210 may be greater than a half of the first distance RD and smaller than two-thirds of the first distance RD. A portion of the support member 210 may be located between the adhesive member AD20 and the vertical portion 143V of the third part 143. For example, the support member 210 may be a black synthetic resin.

Accordingly, it is possible to prevent damage to the display panel 110 caused by an external force.

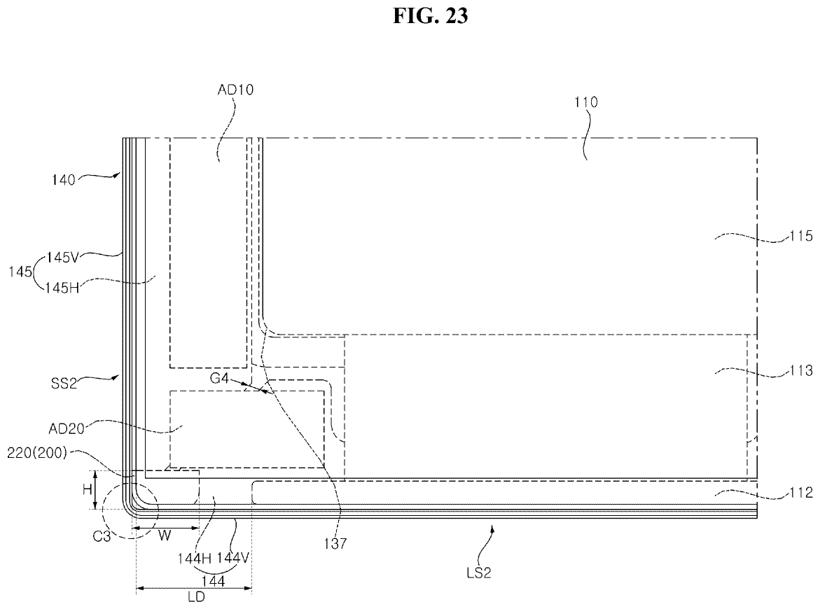

Referring to FIG. 23, a horizontal portion 145H of the fifth part 145 of the side frame 140 may be fixed on the fourth outer part 135d (see FIG. 6) of the material complexed panel 130. The horizontal portion 144H of the fourth part 144 of the side frame 140 may be fixed on the third outer part 135c (see FIG. 6) of the material complexed panel 130. The vertical portion 144V of the fourth part 144 of the side frame 140 may be bent and extend from the vertical portion 145V of the fifth part 145.

The adhesive member AD10 may be fixed on the horizontal portion 145H of the fifth part 145 of the side frame 140. The adhesive member AD10 may be elongated in a longitudinal direction of the fifth part 145 of the side frame 140. The adhesive member AD20 may be fixed on the horizontal portion 144H of the fourth part 144 and the horizontal portion 145H of the fifth part 145. The adhesive member AD20 may cover a gap G4 formed between the horizontal portion 144H of the fourth part 144 and the horizontal portion 145H of the fifth part 145.

The display panel 110 may be fixed to the side frame 140 by the adhesive members AD10 and AD20. The source signal board 115 may be received in the receiving part 137 and may be disposed between the material complexed panel 130 and the display panel 110. The sealing member 112 of the display panel 110 may face the horizontal portion 144H of the fourth part 144 and may be parallel to the vertical portion 144V of the fourth part 144. The sealing member 112 of the display panel 110 may be disposed between the adhesive member AD20, fixed to the horizontal portion 144H of the fourth part 144 and the horizontal portion 145H of the fifth part 145, and the vertical portion 144V of the fourth part 144. The second distance LD of the display panel 110 may be located at the third corner C3 where the second short side SS2 and the second long side LS2 of the display panel 110 meet.

The support member 220 may be disposed adjacent to the third corner C3. The support member 220 may have a height side H and a width side W. The support member 220 may be fixed to the horizontal portions 144H and 145H while covering the horizontal portion 144H of the fourth part 144 and the horizontal portion 145H of the fifth part 145. For example, a size of the width side W may be greater than a size of the height side H.

The height side H of the support member 220 may contact the vertical portion 145V of the fifth part 145, and the width side W of the support member 220 may contact the vertical portion 144V of the fourth part 144. For example, a length of the width side W of the support member 220 may be greater than a half of the second distance LD and smaller than two-thirds of the second distance LD. A portion of the support member 220 may be located between the adhesive member AD20 and the vertical portion 144V of the fourth part 144. For example, the support member 220 may be a black synthetic resin.

Accordingly, it is possible to prevent damage to the display panel 110 caused by an external force.

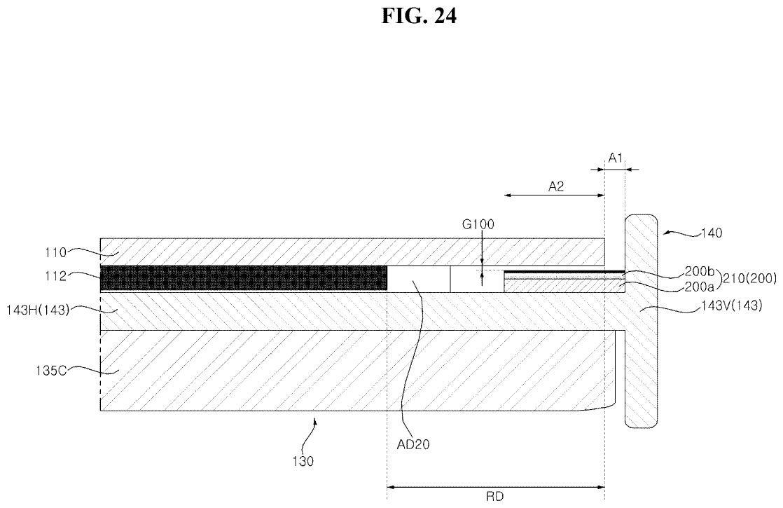

Referring to FIG. 24, the horizontal portion 143H of the third part 143 of the side frame 140 may be fixed to the third outer part 135c of the material complexed panel 130. The display panel 110 may be fixed to the horizontal portion 143H of the side frame 140 by the adhesive member AD20. The vertical portion 143V of the side frame 140 may cover the side surface of the display panel 110 and the side surface of the material complexed panel 130. A first gap Al may be formed between the side surface of the display panel 110 and the vertical portion 143V of the side frame 140.

A thickness of the adhesive member AD20 may be greater than or substantially equal to a thickness of the sealing member 112. A gap between the display panel 110 and the horizontal portion 143H of the side frame 140 may be substantially equal to the thickness of the adhesive member AD20.

The support members 200 and 210 may be fixed to the horizontal portion 143H at a position between the horizontal portion 143H of the side frame 140 and the display panel 110. The support members 200 and 210 may include a first support layer 200a and a second support layer 200b. The second support layer 200b may be located on the first support layer 200a. For example, the second support layer 200b may be attached on the first support layer 200a. In another example, the second support layer 200b may be integrally formed with the first support layer 200a. The hardness of the first support layer 200a may be greater than the hardness of the second support layer 200b. For example, the first support layer 200a may be made of synthetic resin, and the second support layer 200b may be made of rubber or sponge. For example, the second support layer 200b may be a black material or may be painted black. The second support layer 200b may support the rear surface of the display panel 110. The second support layer 200b may contact the rear surface of the display panel 110. A gap G100 between the first support layer 200a and the display panel 110 may be smaller than the thickness of the support members 200 and 210.

The support members 200 and 210 may contact the vertical portion 143V of the side frame 140. A length of the width side W (see FIG. 22) of the support members 200 and 210 may be smaller than the first distance RD. An area A2 where the support members 200 and 210 and the display panel 110 overlap may be greater than the gap Al between the vertical portion 143V of the side frame 140 and the side surface of the display panel 110. The gap Al between the vertical part 143V of the side frame 140 and the side surface of the display panel 110 may be greater than the gap between the display panel 110 and the support members 200 and 210.

Accordingly, it is possible to prevent damage to the display panel 110 even when an external force is applied adjacent to the corners C1, C2, C3, and C4 (see FIG. 1) of the display panel 110.

Referring to FIGS. 1 to 24, a display device includes: a display panel 110 including at least one corner C2, C3; a side frame 140 including a horizontal portion 143H, 144H extending along one side LS2 of the display panel 110 from the at least one corner C2, C3 and facing a rear surface of the display panel 110, and a vertical portion 143V, 144V extending in a direction intersecting the horizontal portion 143H, 144H and covering the one side LS2 of the display panel 110; and a support member 200 fixed to the horizontal portion 143H, 144H at a position between the rear surface of the display panel 110, which is adjacent to the at least one corner C2, C3, and the horizontal portion 143H, 144H of the side frame 140, the support member supporting a rear surface of the corner C2, C3 of the display panel 110.

The display panel 110 may include: an active area AA displaying an image; and a de-active area DA forming a periphery of the active area AA, wherein the one side LS2 of the display panel 110 may define a side surface of the de-active area DA.

The display panel 110 may further include: a sealing member 112 elongated along the one side LS2 of the display panel 110, and fixed to the rear surface of the display panel 110 in the de-active area DA of the display panel 110; a flexible cable 113 connected to the display panel 110 at a position adjacent to the one side LS2 of the display panel 110, the flexible cable 113 electrically connected to the active area AA of the display panel 110; and a source signal board 115 electrically connected to the flexible cable 113, wherein a length of the sealing member 112 may be less than a length of the one side LS2 of the display panel 110.

The support member 200 may be disposed in the de-active area DA of the display panel 110 at a position between the rear surface of the display panel 110, which is not covered by the sealing member 112 of the display panel 110, and the horizontal portion 143H, 144H of the side frame 140.

A thickness of the support member 200 may be greater than a gap G100 between the rear surface of the display panel 110 and an upper surface of the support member 200.

An area A2 where the upper surface of the support member 200 and the display panel 110 overlap may be greater than a gap Al between the vertical portion 143V, 144V of the side frame 140 and the side surface of the display panel 110.

The support member 200 may include: a first support layer 200a fixed to the horizontal portion 143H, 144H of the side frame 140; and a second support layer 200b disposed between the first support layer 200a and the rear surface of the display panel 110, the second support layer 200b stacked on the first support layer 200a.

Hardness of the first support layer 200a may be greater than hardness of the second support layer 200b.

The display device may further include a material complexed plate 130 including fibers, the material complexed plate 130 disposed at a rear of the display panel 110 and coupled with the side frame 140 and the display panel 110, wherein the material complexed plate 130 may include: a front skin 132 facing the display panel 110; a rear skin 133 facing the front skin 132; and a core 131 including the fibers and disposed between the front skin 132 and the rear skin 133.

The material complexed plate 130 may include: a flat part 130P facing a rear surface of the active area AA of the display panel 110; and an outer part 135 depressed down from a front skin 132 of the flat part 130P and formed on a periphery of the flat part 130P, wherein the horizontal portion 143H, 144H of the side frame 140 may be fixed to the outer part 135 of the material complexed plate 130.

The side frame 140 may include: a first part 143, 144 positioned along the one side LS2 of the display panel 110; and a second part 142, 145 positioned along another side SS1 and SS2 of the display panel 110 that is connected to the one side LS2 of the display panel 110 to form the corner C2, C3, wherein the first part 143, 144 may include a first horizontal portion 143H, 144H fixed to the outer part 135c of the material complexed plate 130 and facing the rear surface of the display panel 110, and a first vertical portion 143V, 144V extending in a direction intersecting the first horizontal portion 143H, 144H and covering a side surface of the display panel 110; and the second part 142, 142 may include a second horizontal portion 142H, 145H fixed to the outer part 135b of the material complexed plate 130 and facing the rear surface of the display panel 110, and a second vertical portion 142V, 145V extending in a direction intersecting the second horizontal portion 142H, 145H and covering a side surface of the display panel 110, wherein the first vertical portion 143V, 144V may be bent and extend from the second vertical portion 142V, 145V, and the first horizontal portion 143H, 144H may form a gap G3, G4 with the second horizontal portion 142H, 145H, and the support member 200 may be fixed to the first horizontal portion 143H143H, 144H and the second horizontal portion 142H, 145H while covering the gap G3 and G4.

The support member 200 may have a side surface in contact with at least one of the first vertical portion 143V, 144V or the second vertical portion 142V, 145V.

The material complexed plate 130 may include: a flat part 130P facing a rear surface of the active area AA of the display panel 110; an outer part 135 depressed down from a front skin 132 of the flat part 130P to form a step descending from the flat part 130P, the outer part formed on a periphery of the flat part 130P; a receiving part 137 disposed between the flat part 130P and the outer part 135, the receiving part depressed down from the front skin 132 of the flat part 130P and the front skin 132 of the outer part 135 to form a step descending from the flat part 130P and the outer part 135, wherein the source signal board 115 may be received in the receiving part 137.

The receiving part 137 may extend parallel to the sealing member 112 of the display panel 110.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

The foregoing embodiments are merely examples and are not to be considered as limiting the present disclosure. The scope of the present disclosure should be determined by rational interpretation of the appended claims, and all modifications within the equivalents of the disclosure are intended to be included within the scope of the present disclosure.

1. A display device comprising:
a display panel including at least one corner;
a side frame including a horizontal portion extending along one side of the display panel from the at least one corner and facing a rear surface of the display panel, and a vertical portion extending in a direction intersecting the horizontal portion and covering the one side of the display panel; and
a support member fixed to the horizontal portion at a position between the rear surface of the display panel, which is adjacent to the at least one corner, and the horizontal portion of the side frame, the support member supporting a rear surface of the corner of the display panel.

2. The display device of claim 1, wherein the display panel comprises:
an active area displaying an image; and
a de-active area forming a periphery of the active area,
wherein the one side of the display panel defines a side surface of the de-active area.

3. The display device of claim 2, wherein the display panel furthers comprises:
a sealing member elongated along the one side of the display panel, and fixed to the rear surface of the display panel in the de-active area of the display panel;
a flexible cable connected to the display panel at a position adjacent to the one side of the display panel, the flexible cable electrically connected to the active area of the display panel; and
a source signal board electrically connected to the flexible cable,
wherein a length of the sealing member is less than a length of the one side of the display panel.

4. The display device of claim 3, wherein the support member is disposed in the de-active area of the display panel at a position between the rear surface of the display panel, which is not covered by the sealing member of the display panel, and the horizontal portion of the side frame.

5. The display device of claim 1, wherein a thickness of the support member is greater than a gap between the rear surface of the display panel and an upper surface of the support member.

6. The display device of claim 1, wherein an area where the upper surface of the support member and the display panel overlap is greater than a gap between the vertical portion of the side frame and the side surface of the display panel.

7. The display device of claim 1, wherein the support member comprises:
a first support layer fixed to the horizontal portion of the side frame; and
a second support layer disposed between the first support layer and the rear surface of the display panel, the second support layer stacked on the first support layer.

8. The display device of claim 7, wherein hardness of the first support layer is greater than hardness of the second support layer.

9. The display device of claim 1, further comprising a material complexed plate including fibers, the material complexed plate disposed at a rear of the display panel and coupled with the side frame and the display panel,
wherein the material complexed plate comprises:
a front skin facing the display panel;
a rear skin facing the front skin; and
a core including the fibers and disposed between the front skin and the rear skin.

10. The display device of claim 9, wherein the material complexed plate comprises:
a flat part facing a rear surface of the active area of the display panel; and
an outer part depressed down from a front skin of the flat part and formed on a periphery of the flat part,
wherein the horizontal portion of the side frame is fixed to the outer part of the material complexed plate.

11. The display device of claim 10, wherein the side frame comprises:
a first part positioned along the one side of the display panel; and
a second part positioned along another side of the display panel that is connected to the one side of the display panel to form the corner,
wherein:
the first part comprises a first horizontal portion fixed to the outer part of the material complexed plate and facing the rear surface of the display panel, and a first vertical portion extending in a direction intersecting the first horizontal portion and covering a side surface of the display panel; and
the second part comprises a second horizontal portion fixed to the outer part of the material complexed plate and facing the rear surface of the display panel, and a second vertical portion extending in a direction intersecting the second horizontal portion and covering a side surface of the display panel,
wherein the first vertical portion is bent and extend from the second vertical portion, and the first horizontal portion forms a gap with the second horizontal portion, and the support member is fixed to the first horizontal portion and the second horizontal portion while covering the gap.

12. The display device of claim 11, wherein the support member has a side surface in contact with at least one of the first vertical portion or the second vertical portion.

13. The display device of claim 9, wherein the material complexed plate comprises:
a flat part facing a rear surface of the active area of the display panel;
an outer part depressed down from a front skin of the flat part to form a step descending from the flat part, the outer part formed on a periphery of the flat part; and
a receiving part disposed between the flat part and the outer part, the receiving part depressed down from the front skin of the flat part and the front skin of the outer part to form a step descending from the flat part and the outer part,
wherein the source signal board is received in the receiving part.

14. The display device of claim 13, wherein the receiving part extends parallel to the sealing member of the display panel.
